(19) United States
(12) Patent Application Publication
(10) Pub. No.: US 2023/0042343 A1
(43) Pub. Date: Feb. 9, 2023

(54) IMMERSION TANK, INFORMATION PROCESSING APPARATUS, AND METHOD OF COOLING

(71) Applicant: FUJITSU LIMITED, Kawasaki-shi (JP)

(72) Inventor: Shohei Hashimoto, Yokohama (JP)

(73) Assignee: FUJITSU LIMITED, Kawasaki-shi (JP)

(21) Appl. No.: 17/737,220

(22) Filed: May 5, 2022

(30) Foreign Application Priority Data
Aug. 3, 2021 (JP) 2021-127519

(51) Int. Cl. H05K 7/20

(52) U.S. Cl. CPC H05K 7/20236; H05K 7/20272

(57) ABSTRACT

An immersion tank is used for cooling an electronic circuit. The immersion tank includes a tank body that stores coolant, a housing that is provided inside the tank body and that houses the electronic circuit, a moving member movably supported relative to the tank body, a supply hole which is formed in the housing and through which the coolant is supplied to an inside of the housing, an opening/closing member that is displaced from a closed position at which the opening/closing member closes the supply hole to an open position at which the opening/closing member opens the supply hole, and an operatively associated mechanism that displaces the opening/closing member in accordance with movement of the moving member.

### CROSS-REFERENCE TO RELATED APPLICATION

This application is based upon and claims the benefit of priority of the prior Japanese Patent Application No. 2021-127519, filed on Aug. 3, 2021, the entire contents of which are incorporated herein by reference.

### FIELD

The technique disclosed herein is related to an immersion tank, an information processing apparatus, and a method of cooling.

### BACKGROUND

As a technique for cooling an electronic device (or circuit) by immersing the electronic device in coolant stored in an immersion tank, the following technique is known. For example, an immersion tank includes a tank body, a housing unit, a straightening plate, a flow amount adjusting plate, and an opening/closing plate. The tank body stores the coolant. The housing unit is provided inside the tank body and houses the electronic device. The straightening plate is horizontally disposed below the housing unit. The flow amount adjusting plate moves from a superposed position where the flow amount adjusting plate is superposed over the straightening plate from below to a spaced position where the flow amount adjusting plate is disposed below the straightening plate and spaced from the straightening plate.

The straightening plate has a plurality of straightening holes that penetrate through the straightening plate in the vertical direction. The flow amount adjusting plate has a plurality of flow amount adjusting holes that penetrate through the flow amount adjusting plate in the vertical direction. The plurality of flow amount adjusting holes are respectively formed at positions aligned with the straightening holes. The opening/closing plate moves from a closed position to an open position. At the closed position, the opening/closing plate is superposed over the flow amount adjusting plate from below so as to close the plurality of flow amount adjusting holes. At the open position, the opening/closing plate is disposed below the flow amount adjusting plate and spaced from the flow amount adjusting plate, thereby opening the plurality of flow amount adjusting holes.

The electronic device includes a pushing down member. When the electronic device is housed in the housing unit from above, the pushing down member pushes downward the flow amount adjusting plate and the opening/closing plate so as to move the flow amount adjusting plate to the spaced position or pushes downward the opening/closing plate so as to move the opening/closing plate to the open position.

Japanese Laid-open Patent Publication Nos. 2020-017599 and 2014-225612 are disclosed as related art.

### SUMMARY

According to an aspect of the embodiments, an immersion tank including a tank body that stores coolant, a housing that is provided inside the tank body and that houses an electronic circuit, a moving member movably supported relative to the tank body, a supply hole which is formed in the housing and through which the coolant is supplied to an inside of the housing, an opening/closing member that is displaced from a closed position at which the opening/closing member closes the supply hole to an open position at which the opening/closing member opens the supply hole, and an operatively associated mechanism that displaces the opening/closing member in accordance with movement of the moving member.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a cooling system to which an immersion tank according to an embodiment of the present disclosure is applied;

FIG. 2 is a perspective view of an electronic device illustrated in FIG. 1;

FIG. 3 is a perspective view illustrating the immersion tank and the electronic device illustrated in FIG. 1;

FIG. 4 is a perspective view illustrating the electronic device and an inner structure illustrated in FIG. 3;

FIG. 5 is an enlarged view of part V of FIG. 4;

FIG. 6 is an enlarged view of part VI of FIG. 4;

FIG. 7 is a perspective view illustrating a state where the electronic device is removed from a housing unit illustrated in FIG. 4;

FIG. 8 is an enlarged view of part VIII of FIG. 7;

FIG. 9 is an enlarged view of part IX of FIG. 7;

FIG. 10 is a perspective view illustrating a plurality of opening/closing mechanisms and a plurality of opening/closing members illustrated in FIG. 4;

FIG. 11 is a perspective view illustrating the plurality of opening/closing mechanisms and the plurality of opening/closing members illustrated in FIG. 7;

FIG. 12 is an enlarged view of part XII of FIG. 10;

FIG. 13 is an enlarged view of part XIII of FIG. 11;

FIG. 14 is an enlarged view of part XIV of FIG. 10;

FIG. 15 is an enlarged view of part XV of FIG. 11;

FIG. 16 is a diagram explaining how the electronic device is stored in or removed from the housing unit illustrated in FIG. 4;

FIG. 17 is a diagram explaining operations of an upper portion of an opening/closing mechanism when the electronic device is housed in or removed from the housing unit illustrated in FIG. 4;

FIG. 18 is a diagram explaining operations of a lower portion of the opening/closing mechanism when the electronic device is housed in or removed from the housing unit illustrated in FIG. 4; and

FIG. 19 is a diagram explaining operations of the immersion tank when the electronic device is housed in or removed from the housing unit illustrated in FIG. 4.

### DESCRIPTION OF EMBODIMENTS

According to the technique described in Japanese Laid-open Patent Publication No. 2020-017599, an electronic device includes a pushing down member. The pushing down member extends downward from a device body of the electronic device. Accordingly, in a case where the electronic device includes the pushing down member, the length of the electronic device in the vertical direction increases compared to that in a case where the electronic device does not include the pushing down member. As described above, when the length of the electronic device in the vertical direction increases, the handleability of the electronic device degraded compared to the case where the electronic device does not include the pushing down member.

The technique disclosed in the present application provides, for example, an immersion tank, an information processing apparatus, and a method of cooling with which a coolant may be supplied to the inside of a housing unit when an electronic device is housed in the housing unit without using a pushing down member extending downward from a device body of the electronic device.

An embodiment of the technique disclosed herein will be described with reference to the drawings.

First, the configuration of a cooling system S according to the present embodiment is described.

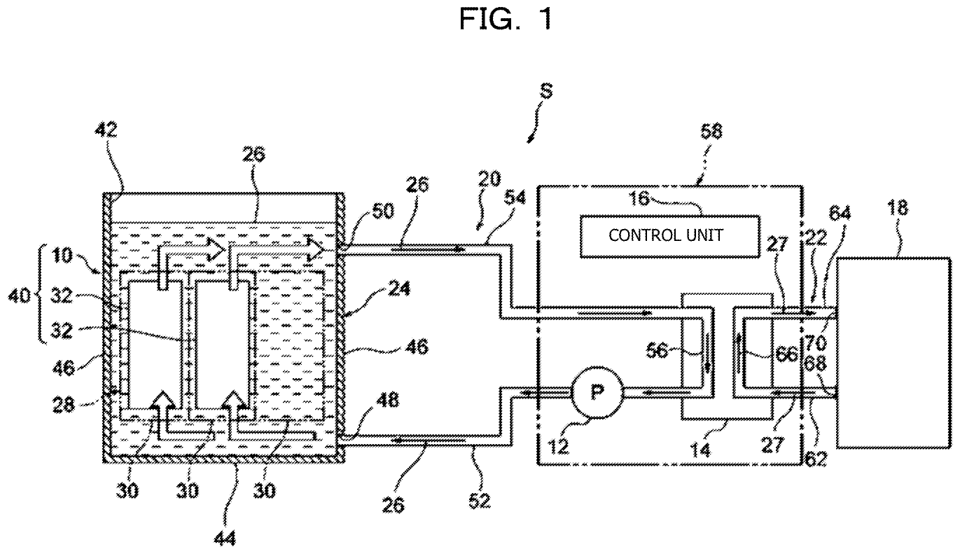

As an example, FIG. 1 illustrates an overall configuration of the cooling system S according to the present embodiment. The cooling system S includes an immersion tank 10, a circulation pump 12, a heat exchanger 14, a control unit 16, a chiller 18, a coolant circulation circuit 20, and a chilled water circulation circuit 22.

The immersion tank 10 includes a box-shaped tank body 24. Coolant 26 is stored in the tank body 24. The coolant 26 is a liquid. As the coolant 26, for example, a fluorinated inert liquid or oil is used as a liquid having an insulating property and exhibiting high cooling efficiency. A housing unit 28 is provided inside the tank body 24. The housing unit 28 includes a plurality of slots 30. In FIG. 1, the housing unit 28 and the plurality of slots 30 are illustrated by phantom lines (for example, two-dot chain lines). Although three slots 30 are illustrated in FIG. 1 as an example, the number of the plurality of slots 30 may be an arbitrary number.

The housing unit 28 houses a plurality of electronic devices 32. For example, the electronic devices 32 are housed in the slots 30 formed inside the housing unit 28. The immersion tank 10 and the plurality of electronic devices 32 are included in an information processing apparatus 40. Although the electronic devices 32 are, for example, information and communication technology (ICT) devices, the electronic devices 32 may be other devices than the ICT devices. A heat generating element such as, for example, a central processing unit (CPU) is mounted in the electronic devices 32.

In the example illustrated as the example in FIG. 1, the electronic devices 32 are housed in two slots 30 out of three slots 30, and no electronic device 32 is housed in the remaining slot 30 out of the three slots 30. When the electronic devices 32 are immersed in the coolant 26 in a state where the electronic devices 32 are housed in the slots 30, the electronic devices 32 are cooled. An upper portion of the immersion tank 10 has an opening 42, and the electronic devices 32 are housed in the housing unit 28 from above the housing unit 28 in the vertical direction through the opening 42. The opening 42 may be closed by a lid (not illustrated).

The tank body 24 includes a bottom plate 44 and a plurality of outer walls 46. The plurality of outer walls 46 are formed around the bottom plate 44. A coolant inlet 48 is formed in a lower portion of one of the plurality of outer walls 46. The coolant 26 flows to the inside of the tank body 24 through the coolant inlet 48. As an example, a coolant outlet 50 is formed in an upper portion of the outer wall 46 in which the coolant inlet 48 is formed. The coolant 26 is discharged from the inside of the tank body 24 through the coolant outlet 50.

The coolant circulation circuit 20 includes an outward pipe 52, a return pipe 54, and a heat exchange portion 56. The outward pipe 52 is coupled to the coolant inlet 48, and the return pipe 54 is coupled to the coolant outlet 50. The heat exchange portion 56 couples the outward pipe 52 and the return pipe 54 to each other. The heat exchange portion 56 is provided in the heat exchanger 14.

The circulation pump 12 is, as an example, provided in the outward pipe 52. The control unit 16 includes, for example, an electronic circuit including a CPU, a read-only memory (ROM), a random-access memory (RAM), and so forth and is electrically coupled to the circulation pump 12. The control unit 16 controls the number of revolutions of the circulation pump 12. The circulation pump 12, the heat exchanger 14, and the control unit 16 are included in a heat exchanger unit 58.

The chilled water circulation circuit 22 includes an outward pipe 62, a return pipe 64, and a heat exchange portion 66. The outward pipe 62 is coupled to a supply port 68 provided in the chiller 18, and the return pipe 64 is coupled to a collection port 70 provided in the chiller 18. The heat exchange portion 66 couples the outward pipe 62 and the return pipe 64 to each other. The heat exchange portion 66 is provided in the heat exchanger 14. In the heat exchanger 14, the heat exchange portion 56 and the heat exchange portion 66 are thermally coupled to each other.

In the cooling system S, when the circulation pump 12 is operated, the coolant 26 circulates between the immersion tank 10 and the heat exchanger 14 through the coolant circulation circuit 20. Furthermore, chilled water 27 circulates between the chiller 18 and the heat exchanger 14 through the chilled water circulation circuit 22. In the heat exchanger 14, the coolant 26 is cooled by the chilled water 27. The coolant 26 cooled by the heat exchanger 14 is supplied to the immersion tank 10. In the immersion tank 10, the coolant 26 flows to the inside of the tank body 24 through the coolant inlet 48. The coolant 26 having flowed to the inside of the tank body 24 flows from a lower portion toward an upper portion of the tank body 24 and is discharged to the outside of the tank body 24 through the coolant outlet 50.

Next, the configuration of an electronic device 32 will be described.

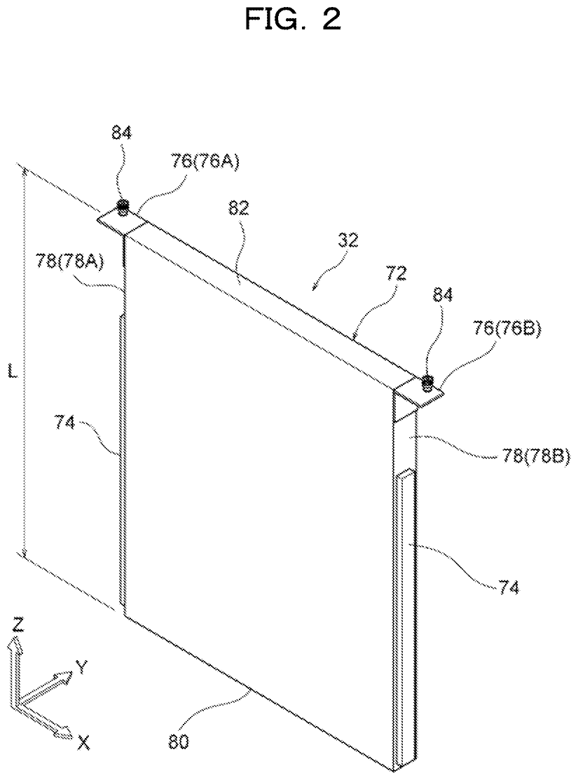

As an example, FIG. 2 illustrates the electronic device 32 according to the present embodiment. The electronic device 32 includes a device body 72, a pair of guide rails 74, and a pair of flanges 76. The X direction indicates a lateral width direction of the electronic device 32, the Y direction indicates a thickness direction of the electronic device 32, and the Z direction indicates a depth direction of the electronic device 32. The X, Y, and Z directions are directions perpendicular to each other. When the electronic device 32 is housed in the slot 30 (see FIG. 1), the Z direction corresponds to the vertical direction.

As an example, the device body 72 is a rectangular parallelepiped that is flat in the Y direction. The device body 72 has a pair of side surfaces 78. The pair of side surfaces 78 are separated from each other in the X direction. Hereinafter, in a case where the pair of side surfaces 78 are distinctively described, one of the pair of side surfaces 78 is referred to as a first side surface 78A, and an other of the pair of side surfaces 78 is referred to as a second side surface 78B. Each of the pair of guide rails 74 is provided at a corresponding one of the pair of side surfaces 78. Each of the pair of guide rails 74 extends linearly in the Z direction.

The device body 72 includes a leading end portion 80 and a trailing end portion 82. The leading end portion 80 is a portion positioned at a lower end of the electronic device 32 in a case where the electronic device 32 is housed in the slot 30 (see FIG. 1). The trailing end portion 82 is a portion positioned at an upper end of the electronic device 32 in a case where the electronic device 32 is housed in the slot 30. The length of the device body 72 in the Z direction may vary depending on the type of the electronic device 32. For example, in a case where the electronic device 32 is a local area network (LAN) switch, the length of the device body 72 in the Z direction is smaller than that in a case where the electronic device 32 is an information processing device. As an example, FIG. 2 illustrates the electronic device 32 that is the information processing device.

The pair of flanges 76 are provided at the trailing end portion 82 of the device body 72. Each of the pair of flanges 76 is formed to have a plate shape the thickness direction of which is in the Z direction. Hereinafter, in a case where the pair of flanges 76 are distinctively described, one of the pair of flanges 76 is referred to as a first flange 76A, and an other of the pair of flanges 76 is referred to as a second flange 76B.

The first flange 76A projects toward a first side of the device body 72 relative to the first side surface 78A. The second flange 76B projects, relative to the second side surface 78B, toward a second side of the device body 72 opposite to the first side. A panel fastener 84 is provided at each of the pair of flanges 76. A screw may be used instead of the panel fastener 84.

Next, the configuration of the immersion tank 10 will be described.

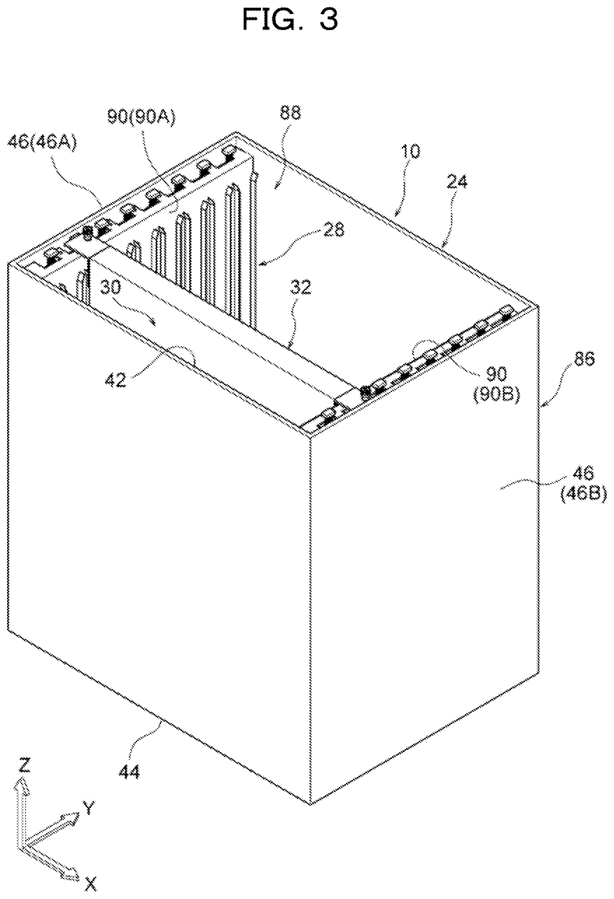

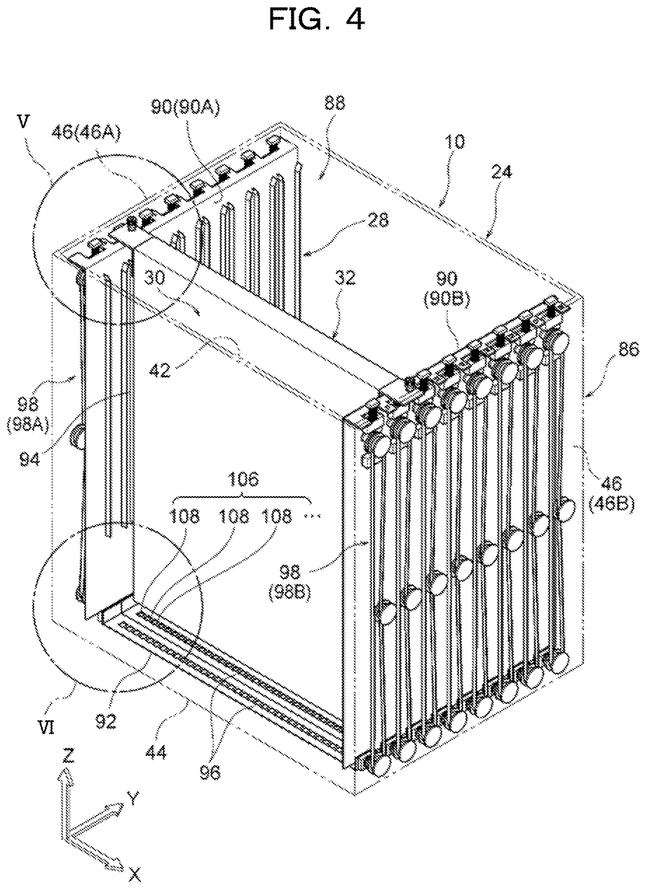

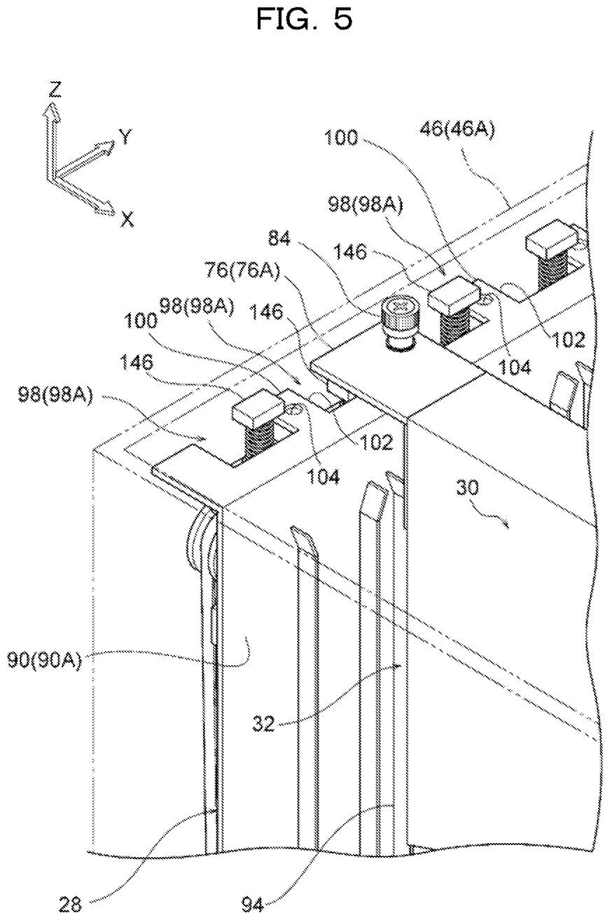

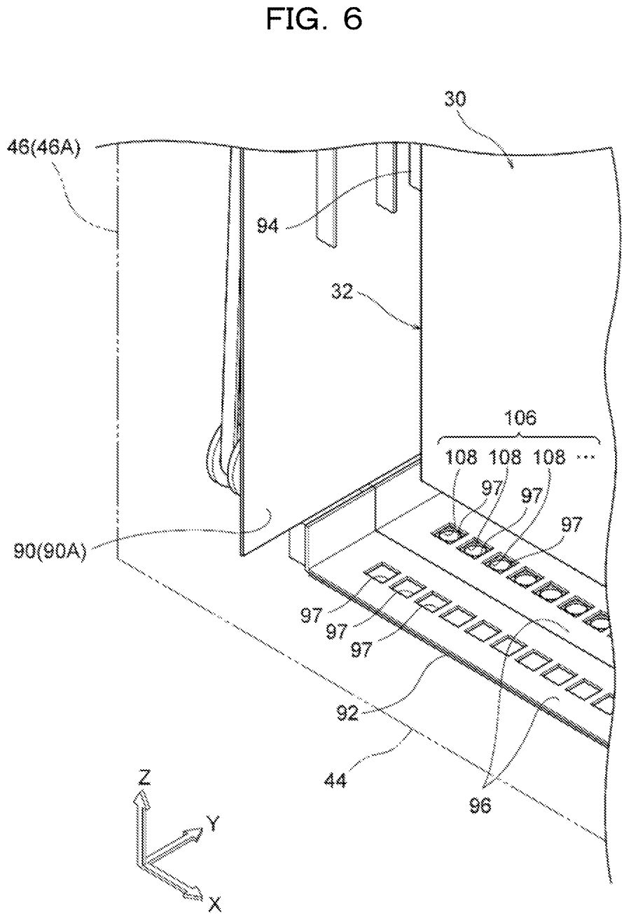

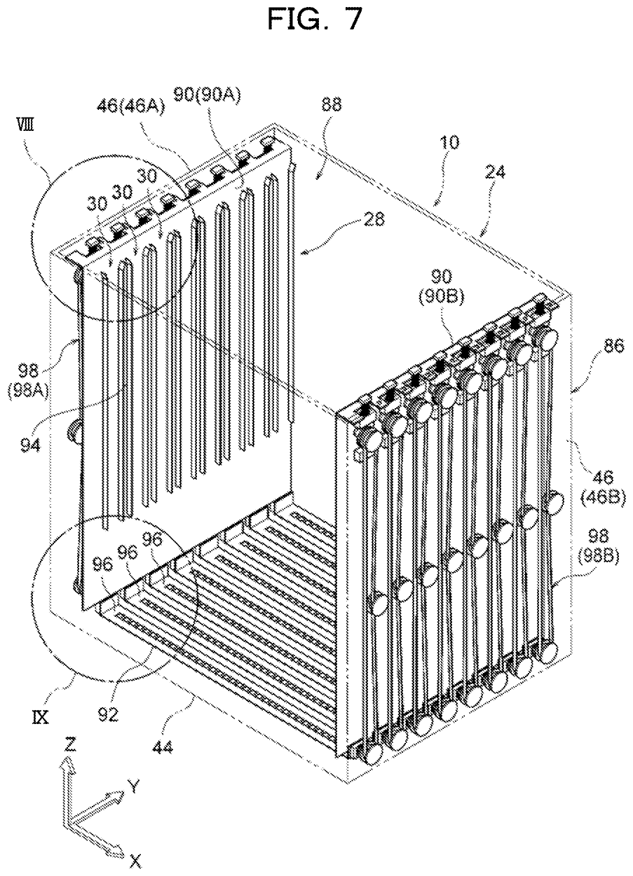

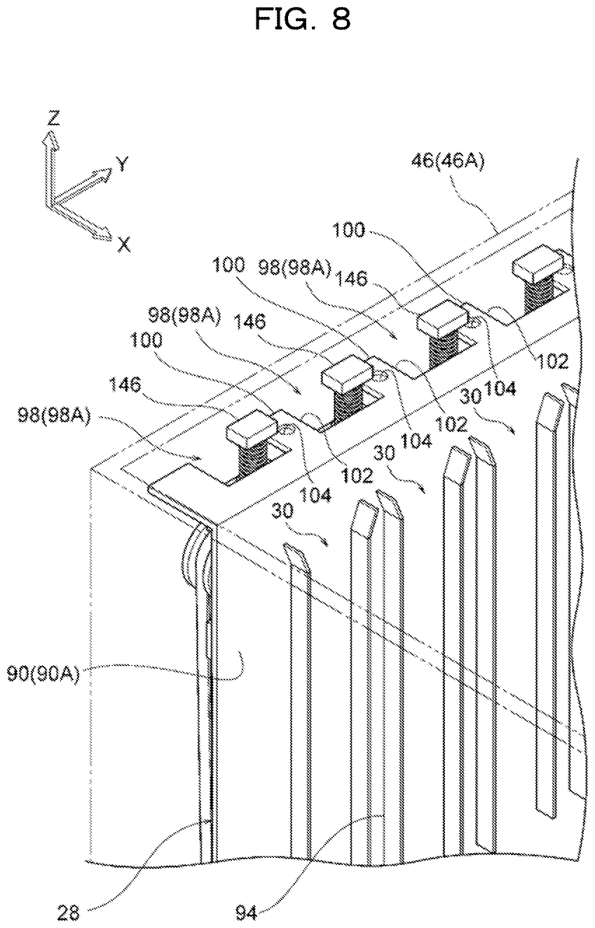

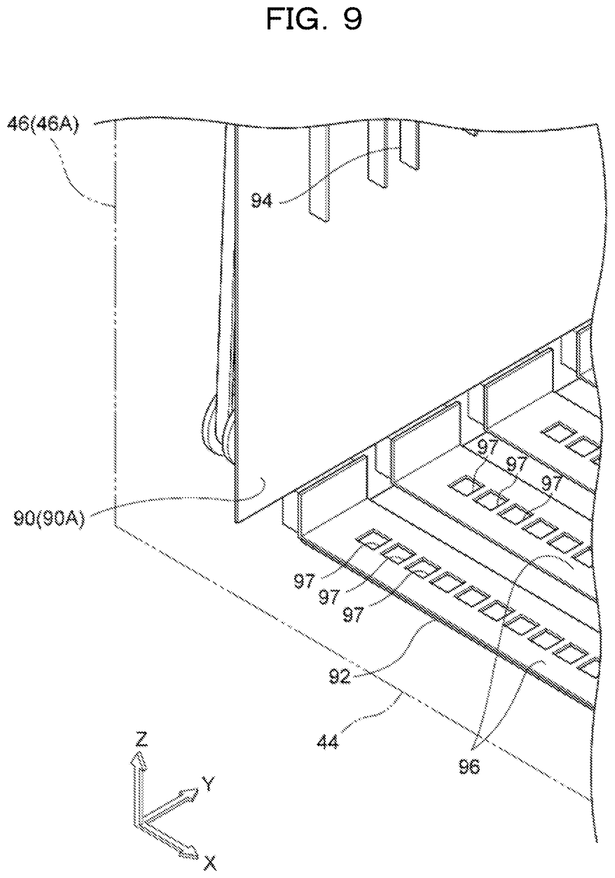

As an example, FIGS. 3 to 6 illustrate the state where the electronic device 32 is housed in the housing unit 28 provided inside the tank body 24. As an example, FIGS. 7 to 9 illustrate a state where no electronic device 32 is housed in the housing unit 28. In FIG. 3, the tank body 24 is illustrated by solid lines. In FIGS. 4 to 9, the tank body 24 is illustrated by phantom lines (for example, two-dot chain lines) for ease of understanding of the configuration of an inner structure 88. FIG. 5 illustrates an enlarged view of part V of FIG. 4. FIG. 6 illustrates an enlarged view of part VI of FIG. 4. FIG. 8 illustrates an enlarged view of part VIII of FIG. 7. FIG. 9 illustrates an enlarged view of part IX of FIG. 7.

As the example, eight slots 30 are provided in the housing unit 28. FIGS. 3 to 6 illustrate, as an example, the state where the electronic device 32 is housed in one of the eight slots 30. The X direction indicates the lateral width direction of the immersion tank 10, the Y direction indicates the thickness direction of the immersion tank 10, and the Z direction indicates the height direction of the electronic device 32. In a case where the immersion tank 10 is horizontally installed, the Z direction corresponds to the vertical direction.

The immersion tank 10 includes the tank body 24 and the inner structure 88. The inner structure 88 is provided inside the tank body 24. The inner structure 88 includes a pair of inner walls 90, a bottom plate 92, a plurality of rails 94, a plurality of opening/closing members 96, and a plurality of opening/closing mechanisms 98.

The pair of inner walls 90 and the bottom plate 92 are fixed to the tank body 24 by a fixing member (not illustrated) or the like. The pair of inner walls 90 are disposed so as to face each other in the X direction. Hereinafter, in a case where the pair of inner walls 90 are distinctively described, one of the pair of inner walls 90 is referred to as a first inner wall 90A, and an other of the pair of inner walls 90 is referred to as a second inner wall 90B. Hereinafter, in a case where the pair of outer walls 46 respectively facing the first inner wall 90A and the second inner wall 90B out of the plurality of outer walls 46 are separately described, one of the pair of outer walls 46 is referred to as a first outer wall 46A, and an other of the pair of outer walls 46 is referred to as a second outer wall 46B.

The first inner wall 90A is disposed at an inner position in the tank body 24 than the first outer wall 46A. The second inner wall 90B is disposed at an inner position in the tank body 24 than the second outer wall 46B. The first inner wall 90A faces the first outer wall 46A in the X direction. The second inner wall 90B faces the second outer wall 46B in the X direction.

The bottom plate 92 of the inner structure 88 is disposed above the bottom plate 44 of the tank body 24. The bottom plate 92 is disposed so as to face the bottom plate 44 in the Z direction. The coolant inlet 48 (see FIG. 1) is positioned between the bottom plate 44 and the bottom plate 92 in the Z direction. The coolant 26 (see FIG. 1) flows into a space between the bottom plate 44 and the bottom plate 92 through the coolant inlet 48.

The pair of inner walls 90 and the bottom plate 92 form the housing unit 28 in which the plurality of electronic devices 32 may be housed. For example, the housing unit 28 is formed in a recessed shape having the pair of inner walls 90 and the bottom plate 92. A space between the pair of inner walls 90 is formed as the plurality of slots 30 in which the plurality of electronic devices 32 may be respectively stored. As an example, the plurality of slots 30 are arranged in the Y direction.

Each of the plurality of rails 94 is provided at the first inner walls 90A or the second inner walls 90B. In FIGS. 4 and 7, only rails 94 provided at the first inner wall 90A out of the plurality of rails 94 are illustrated, and out of pairs of rails 94, rails 94 provided at the second inner walls 90B are hidden by the second inner walls 90B and not illustrated. Each of the plurality of rails 94 is fixed to a surface (for example, an inner side surface) of the first inner wall 90A or the second inner wall 90B that face each other. The rails 94 provided at the first inner wall 90A are arranged in the Y direction. Likewise, the rails 94 provided at the second inner wall 90B are arranged in the Y direction.

A pair of rails 94 paired with each other in the X direction are allocated to each of the slots 30. Each of the rails 94 extends linearly in the Z direction. Each of the rails 94 is formed to have a groove shape. The guide rails 74 (see FIG. 2) provided at the side surfaces 78 of the electronic device 32 are respectively inserted into the inside of the rails 94. In a case where the electronic device 32 is housed in the slot 30, the guide rails 74 are respectively inserted into the rails 94, thereby the electronic device 32 is guided in the Z direction. Furthermore, in the state where the electronic device 32 is housed in the slot 30, the guide rails 74 are respectively restrained by the rails 94, thereby the electronic device 32 is positioned relative to the slot 30.

A plurality of fixing portions 100 are provided at an upper end portion of the housing unit 28. As an example, the fixing portions 100 are formed by bent pieces formed at upper end portions of the inner walls 90. Each of the fixing portions 100 is formed such that the thickness direction of the fixing portion 100 is the Z direction. Each of the plurality of fixing portions 100 is formed over the first inner wall 90A or the second inner wall 90B. The fixing portions 100 formed at an upper end portion of the first inner wall 90A are arranged in the Y direction. The fixing portions 100 formed at the upper end portion of the first inner wall 90A extend from the upper end portion of the first inner wall 90A toward the first outer wall 46A.

Although it is not particularly illustrated, the fixing portions 100 formed at the upper end portion of the second inner wall 90B and the fixing portions 100 formed at the upper end portion of the first inner wall 90A are arranged in a line-symmetric manner in the X direction. Cutout portions 102 are formed between the adjacent fixing portions 100. The cutout portions 102 are formed to have a shape cut from a distal end side to a proximal end side of the fixing portions 100.

Screw holes 104 are formed in the respective fixing portions 100. Each of the screw holes 104 is formed such that the axial direction of which is the Z direction, and the screw hole 104 penetrates the fixing portion 100 in the Z direction. In a state where the electronic device 32 is housed in the slot 30, the flanges 76 are superposed over the fixing portions 100 from above. In a state where the flanges 76 are superposed over the fixing portions 100 from above, the panel fasteners 84 are disposed so as to be coaxial with the respective screw holes 104. By screwing screw portions of the panel fasteners 84 into the screw holes 104, the flanges 76 are fixed to the fixing portions 100. Also, when the flanges 76 are fixed to the fixing portions 100, the electronic device 32 is fixed to the tank body 24 by using the housing unit 28.

A plurality of supply hole rows 106 are formed in the bottom plate 92 of the inner structure 88. Each of the supply hole rows 106 has a plurality of supply holes 108. Each of the supply holes 108 penetrates the bottom plate 92 in the Z direction. The plurality of supply holes 108 included in each of the supply hole rows 106 are arranged in the X direction. The plurality of supply hole rows 106 are provided so as to correspond to the plurality of slots 30, respectively. For example, the supply hole row 106 is provided in each of the slots 30. Instead of each of the supply hole rows 106, a supply hole having a slotted hole shape extending in the X direction may be formed.

FIG. 4 illustrates a state where the plurality of supply holes 108 included in the supply hole row 106 corresponding to the slot 30 in which the electronic device 32 is housed are open and the supply holes 108 included in other supply hole rows 106 are closed by the opening/closing members 96, which will be described later. FIG. 7 illustrates a state where the supply holes 108 included in all the supply hole rows 106 are closed by the opening/closing members 96.

In a state where the plurality of supply holes 108 are open, the coolant 26 (see FIG. 1) having flowed into the space between the bottom plate 44 and the bottom plate 92 through the coolant inlet 48 (see FIG. 1) is supplied to the inside of the housing unit 28 (for example, the slot 30) through the plurality of supply holes 108. The electronic device 32 is cooled by the coolant 26 supplied to the slot 30.

The plurality of opening/closing members 96 are each provided so as to correspond to a corresponding one of the plurality of slots 30. For example, the opening/closing member 96 is provided at each of the slots 30. The plurality of opening/closing members 96 correspond to the plurality of supply hole rows 106, respectively. Each of the opening/closing members 96 is formed to have an elongated plate shape extending in the X direction. The plurality of opening/closing members 96 are provided at the bottom plate 92.

As an example, each of the opening/closing members 96 is superposed over the bottom plate 92 from above the bottom plate 92. However, the opening/closing member 96 may be superposed over the bottom plate 92 from below the bottom plate 92. The opening/closing member 96 is supported so as to be displaceable in the horizontal direction with respect to the bottom plate 92. As an example, the opening/closing member 96 is supported so as to be displaceable in the Y direction relative to the bottom plate 92. Although the opening/closing member 96 is indirectly supported relative to the tank body 24 by using the bottom plate 92, the opening/closing member 96 may be directly supported relative to the tank body 24.

Each of the opening/closing members 96 has a plurality of communication holes 97 that respectively correspond to the plurality of supply holes 108. The opening/closing member 96 is displaced between a closed position at which the opening/closing member 96 closes the plurality of supply holes 108 included in the supply hole row 106 and an open position at which the opening/closing member 96 opens the plurality of supply holes 108. In a state where the opening/closing member 96 is positioned at the open position, the plurality of supply holes 108 and the plurality of communication holes 97 communicate with each other. In a state where the opening/closing member 96 is positioned at the closed position, the plurality of supply holes 108 and the plurality of communication holes 97 are shifted from each other. In the state where the plurality of supply holes 108 and the plurality of communication holes 97 are shifted from each other, the plurality of supply holes 108 are closed by the opening/closing members 96.

FIG. 4 illustrates a state where the opening/closing member 96 corresponding to the slot 30 in which the electronic device 32 is housed is positioned at the open position and other opening/closing members 96 are positioned at the closed position. FIG. 7 illustrates a state where all the opening/closing members 96 are positioned at the closed position.

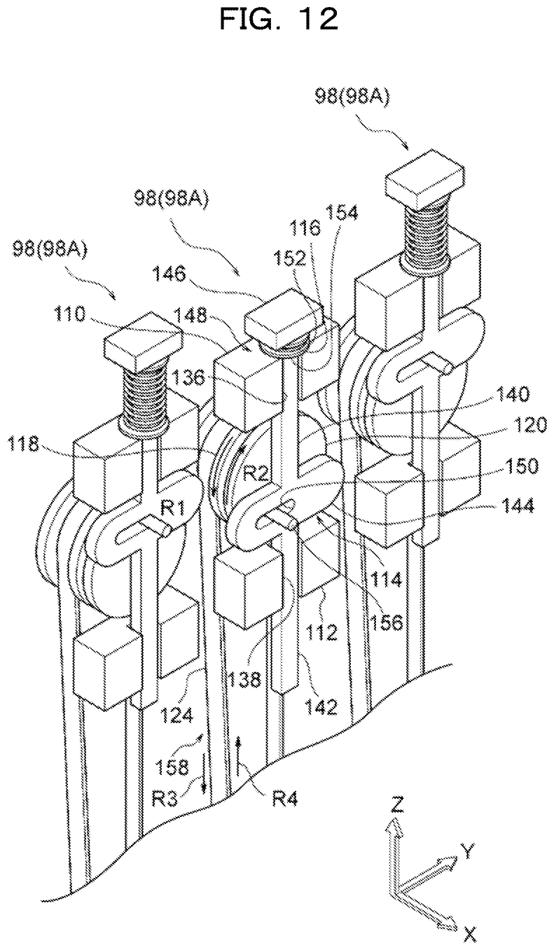

The plurality of opening/closing mechanisms 98 are separately disposed on a first side and a second side of the housing unit 28. Hereinafter, the opening/closing mechanisms 98 disposed on the first side of the housing unit 28 and the opening/closing mechanisms 98 disposed on the second side of the housing unit 28 may be distinctively described. In this case, the opening/closing mechanisms 98 disposed on the first side of the housing unit 28 are referred to as first opening/closing mechanisms 98A, and the opening/closing mechanisms 98 disposed on the second side of the housing unit 28 are referred to as second opening/closing mechanisms 98B. The first opening/closing mechanisms 98A and the second opening/closing mechanisms 98B are arranged in a point-symmetric manner. However, slotted holes 150 of moving members 114 provided in the first opening/closing mechanisms 98A, which will be described later (in FIG. 12), and slotted holes 150 of moving members 114 provided in the second opening/closing mechanisms 98B are arranged in a line-symmetric manner.

A plurality of the first opening/closing mechanisms 98A are arranged in the Y direction. Likewise, a plurality of the second opening/closing mechanisms 98B are arranged in the Y direction. The plurality of first opening/closing mechanisms 98A are each provided so as to correspond to a corresponding one of the plurality of slots 30. Likewise, the plurality of second opening/closing mechanisms 98B are each provided so as to correspond to a corresponding one of the plurality of slots 30. For example, a pair of opening/closing mechanisms 98 paired in the X direction are assigned to an each of the slots 30.

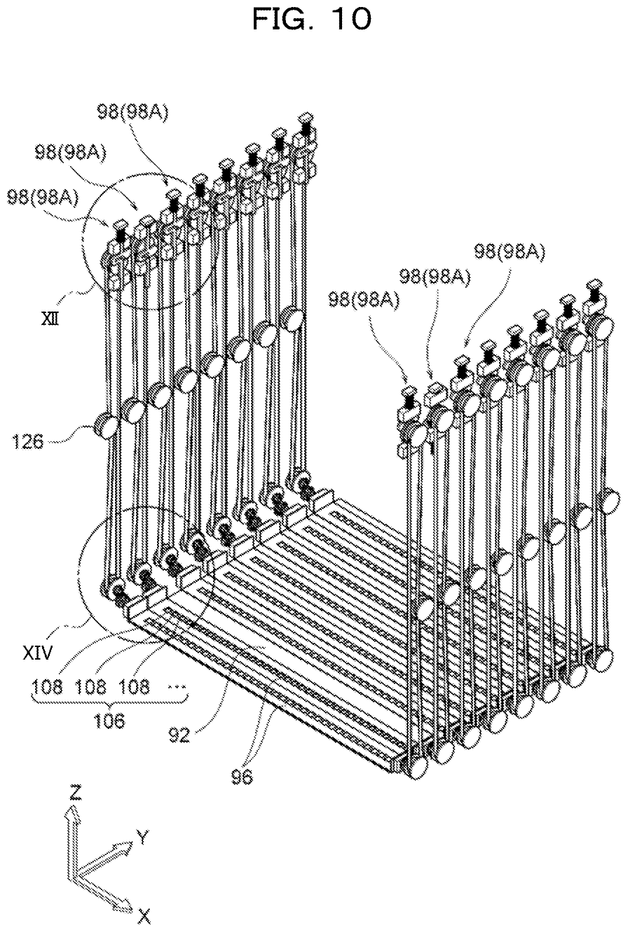

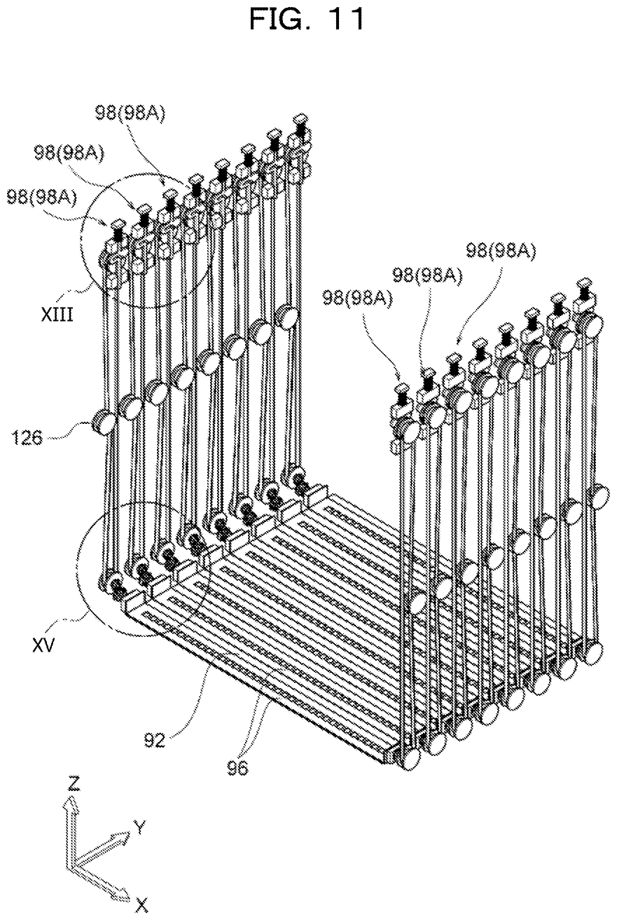

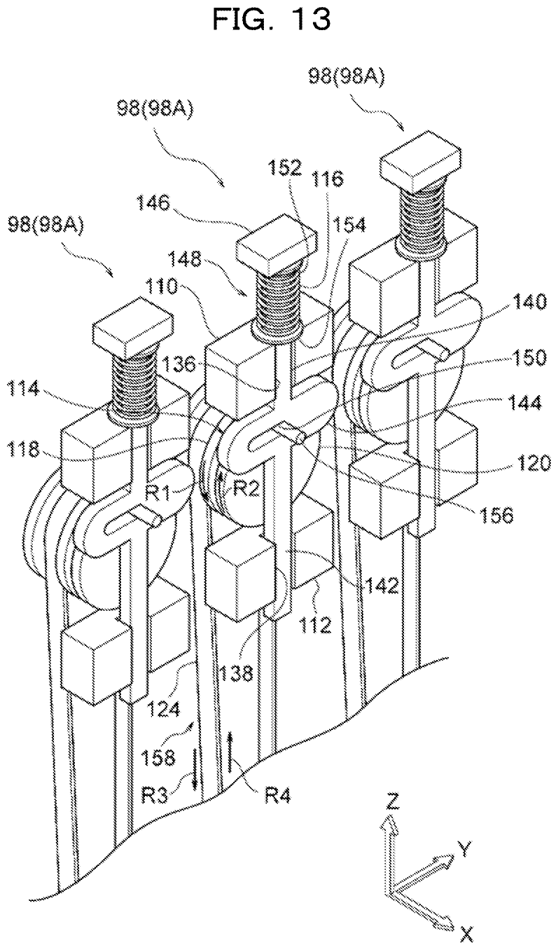

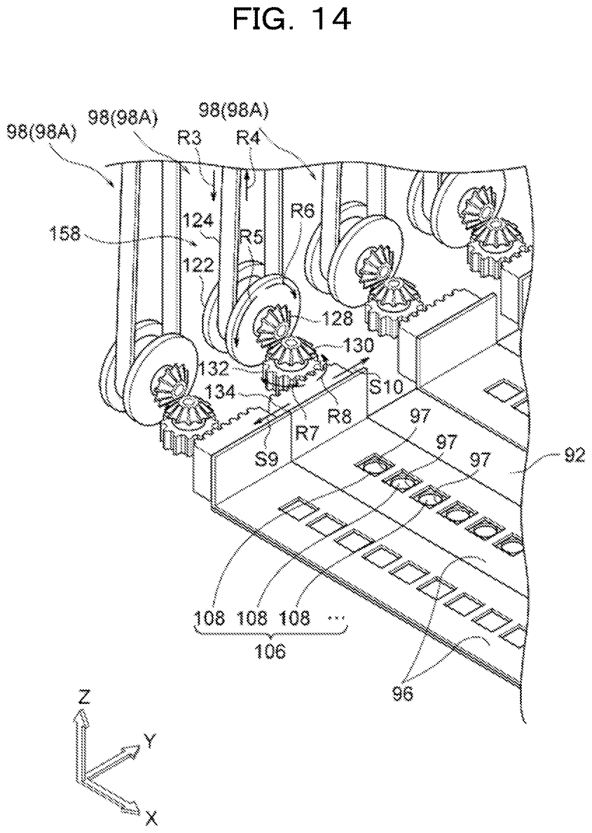

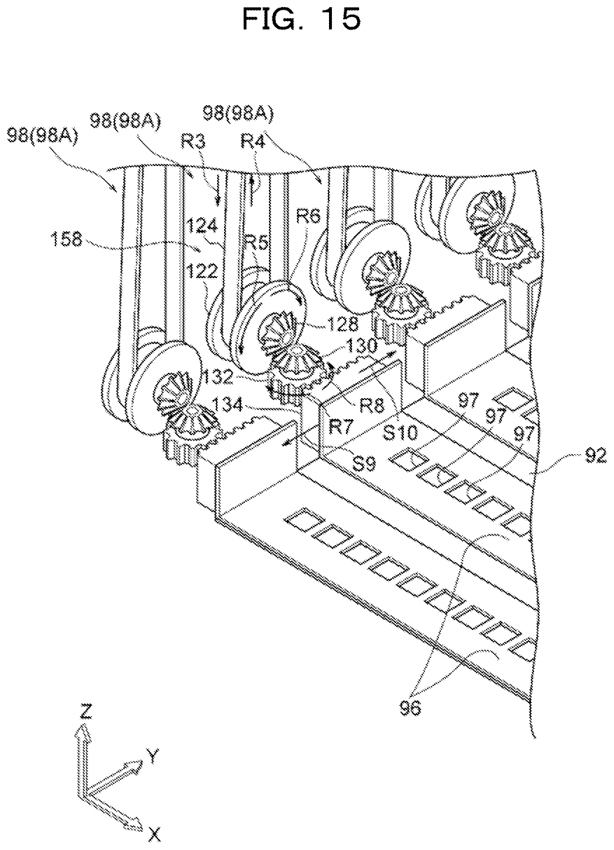

As an example, FIG. 10 illustrates the plurality of opening/closing mechanisms 98 and the plurality of opening/closing members 96 in the case where the electronic device 32 is housed in one of the slots 30 as illustrated in FIG. 4. As an example, FIG. 11 illustrates the plurality of opening/closing mechanisms 98 and the plurality of opening/closing members 96 in the case where, as illustrated in FIG. 7, no electronic device 32 is housed in the slot 30. Illustration of the pair of inner walls 90 (see FIGS. 4 and 7) is omitted from FIGS. 10 and 11 for ease of understanding of the configuration of the opening/closing mechanisms 98. FIG. 12 illustrates an enlarged view of part XII of FIG. 10. FIG. 13 illustrates an enlarged view of part XIII of FIG. 11. FIG. 14 illustrates an enlarged view of part XIV of FIG. 10. FIG. 15 illustrates an enlarged view of part XV of FIG. 11.

The opening/closing mechanisms 98 each include a first guide member 110, a second guide member 112, a moving member 114, and an urging member 116. The opening/closing mechanism 98 also includes a first pulley 118, a rotating member 120, a second pulley 122, a belt 124, a tension pulley 126, a first gear 128, a second gear 130, a pinion 132, and a rack 134.

The first guide member 110 is disposed above the second guide member 112. Each of the first guide member 110 and the second guide member 112 is fixed to the inner wall 90 (see FIG. 4). A first groove 136 is formed in the first guide member 110, and a second groove 138 is formed in the second guide member 112. Each of the first groove 136 and the second groove 138 extends in the Z direction.

The moving member 114 includes a first sliding portion 140, a second sliding portion 142, a body portion 144, and a pushing target portion 146. The first sliding portion 140 and the second sliding portion 142 are each formed to have a rod shape extending in the Z direction. The first sliding portion 140 extends upward from the body portion 144, and the second sliding portion 142 extends downward from the body portion 144. The first sliding portion 140 is inserted into the first groove 136, and the second sliding portion 142 is inserted into the second groove 138.

When the first sliding portion 140 is inserted into the first groove 136 and the second sliding portion 142 is inserted into the second groove 138, the moving member 114 is movably supported in the Z direction relative to the inner wall 90. Although the moving member 114 is indirectly supported relative to the tank body 24 (see FIG. 4) by using the inner wall 90, the moving member 114 may be directly supported relative to the tank body 24.

The moving member 114 includes a projecting portion 148 that projects to an upper side compared to the upper end portion (for example, the fixing portion 100) of the housing unit 28 (see FIGS. 5 and 8). The projecting portion 148 is formed by an upper end portion of the first sliding portion 140. The pushing target portion 146 is provided at an upper end portion of the projecting portion 148. The pushing target portion 146 is provided at a position at which the pushing target portion 146 is pushed downward by the flange 76 (see FIG. 5) when the electronic device 32 (see FIGS. 4 and 5) is housed in the slot 30.

In the case where the electronic device 32 is housed in the slot 30, the pushing target portion 146 is pushed downward by the flange 76, thereby the pushing target portion 146 is positioned below the flange 76 (for example, the trailing end portion 82 of the electronic device 32). In the case where the electronic device 32 is housed in the slot 30, the pushing target portion 146 is positioned above the leading end portion 80 of the electronic device 32. A length range between the leading end portion 80 and the trailing end portion 82 of the electronic device 32 corresponds to a length range L (see FIG. 2) of the electronic device 32 in the vertical direction. In the case where the electronic device 32 is housed in the slot 30, the pushing target portion 146 is contained within the length range L of the electronic device 32 in the vertical direction.

The slotted hole 150 is formed in the body portion 144 of the moving member 114. As an example, the slotted hole 150 extends in the Y direction. The urging member 116 is supported at the first sliding portion 140. As an example, the urging member 116 is a coil spring. Instead of the coil spring, any of various types of springs such as a torsion spring may be used as the urging member 116. The urging member 116 is provided between a first guide and the pushing target portion 146. A first washer 152 is provided between the urging member 116 and the pushing target portion 146, and a second washer 154 is provided between the urging member 116 and the first guide.

When the pushing target portion 146 is pushed downward by the flange 76, the moving member 114 moves downward. This causes the urging member 116 to be compressed. When the urging member 116 is compressed, the urging member 116 causes an upward urging force to be applied to the moving member 114.

The first pulley 118 is provided so as to be coaxial with the rotating member 120. The rotating member 120 is provided so as to be integral with the first pulley 118. The first pulley 118 and the rotating member 120 are disposed at an upper portion of the inner wall 90. The first pulley 118 and the rotating member 120 are disposed such that the axial direction of the first pulley 118 and the rotating member 120 is the X direction. A pin 156 extending in the X direction is provided at the rotating member 120. The pin 156 is provided at an eccentric position relative to the central axis of the rotating member 120. Although the pin 156 is provided indirectly at the first pulley 118 by using the rotating member 120, the rotating member 120 may be omitted and the pin 156 may be provided directly at the first pulley 118.

The pin 156 is inserted into the slotted hole 150. The pin 156 and the slotted hole 150 form a Scotch yoke mechanism. When the moving member 114 moves downward, the pin 156 moves in the slotted hole 150. This causes the first pulley 118 and the rotating member 120 to rotate in a first direction R1. When the moving member 114 moves upward, the pin 156 moves in the slotted hole 150. This causes the second pulley 122 and the rotating member 120 to rotate in a second direction R2.

The second pulley 122 is disposed below the first pulley 118. As an example, the second pulley 122 is disposed at a lower portion of the inner wall 90. The second pulley 122 is disposed such that the axial direction of the second pulley 122 is the X direction. The second pulley 122 is rotatably supported relative to the inner wall 90. The belt 124 is formed to have an annular shape. The belt 124 is looped over the first pulley 118 and the second pulley 122.

The tension pulley 126 is disposed between the first pulley 118 and the second pulley 122 in the Z direction. The tension pulley 126 is disposed such that the axial direction of which is the X direction. The tension pulley 126 is rotatably supported relative to the inner wall 90. By pressing the belt 124 in the Y direction, the tension pulley 126 applies tension to the belt 124.

The first gear 128 is provided so as to be coaxial with the second pulley 122. The first gear 128 is provided so as to be integral with the second pulley 122. The first gear 128 is disposed such that the axial direction of which is the X direction. The second gear 130 is disposed such that the axial direction of which is the Z direction. The first gear 128 and the second gear 130 are, for example, bevel gears. The second gear 130 is engaged with the first gear 128.

The pinion 132 is provided so as to be coaxial with the second gear 130. The pinion 132 is provided so as to be integral with the second gear 130. The rack 134 is provided at the opening/closing member 96. As an example, the rack 134 extends in the Y direction. The rack 134 is engaged with the pinion 132. The rack 134 and the pinion 132 form a rack and pinion mechanism.

In the opening/closing mechanism 98, when the first pulley 118 rotates in the first direction R1 when the moving member 114 moves downward, the belt 124 rotates in a third direction R3. When the belt 124 rotates in the third direction R3, the second pulley 122 and the first gear 128 rotate in a fifth direction R5. When the first gear 128 rotates in the fifth direction R5, the second gear 130 and the pinion 132 rotate in a seventh direction R7. When the pinion 132 rotates in the seventh direction R7, the rack 134 and the opening/closing member 96 slide in a ninth direction S9. When the opening/closing member 96 slides in the ninth direction S9, the opening/closing member 96 is displaced from the closed position to the open position.

In the opening/closing mechanism 98, when the first pulley 118 rotates in the second direction R2 when the moving member 114 moves upward, the belt 124 rotates in a fourth direction R4. When the belt 124 rotates in the fourth direction R4, the second pulley 122 and the first gear 128 rotate in a sixth direction R6. When the first gear 128 rotates in the sixth direction R6, the second gear 130 and the pinion 132 rotate in an eighth direction R8. When the pinion 132 rotates in the eighth direction R8, the rack 134 and the opening/closing member 96 slide in a tenth direction S10. When the opening/closing member 96 slides in the tenth direction S10, the opening/closing member 96 is displaced from the open position to the closed position.

In the opening/closing mechanism 98, the first pulley 118, the rotating member 120, the second pulley 122, the belt 124, the tension pulley 126, the first gear 128, the second gear 130, the pinion 132, and the rack 134 form an operatively associated mechanism 158. The operatively associated mechanism 158 is a mechanism that displaces the opening/closing member 96 in accordance with the movement of the moving member 114.

The moving member 114 is disposed between the outer wall 46 and the inner wall 90 (see FIG. 3). Out of a plurality of the elements included in the operatively associated mechanism 158, the first pulley 118, the rotating member 120, the second pulley 122, the belt 124, the tension pulley 126, the first gear 128, the second gear 130, and the pinion 132 are disposed between the outer wall 46 and the inner wall 90. Although the rack 134 is disposed between the inner wall 90 and the bottom plate 92, all of the plurality of elements included in the operatively associated mechanism 158 may be disposed between the outer wall 46 and the inner wall 90.

The moving member 114 included in the first opening/closing mechanism 98A is an example of a “first moving member” according to the technique of the present disclosure. The moving member 114 included in the second opening/closing mechanism 98B is an example of a “second moving member” according to the technique of the present disclosure. The operatively associated mechanism 158 included in the first opening/closing mechanism 98A is an example of a “first operatively associated mechanism” according to the technique of the present disclosure. The operatively associated mechanism 158 included in the second opening/closing mechanism 98B is an example of a “second operatively associated mechanism” according to the technique of the present disclosure.

Next, a method of cooling the electronic device 32 using the immersion tank 10 will be described.

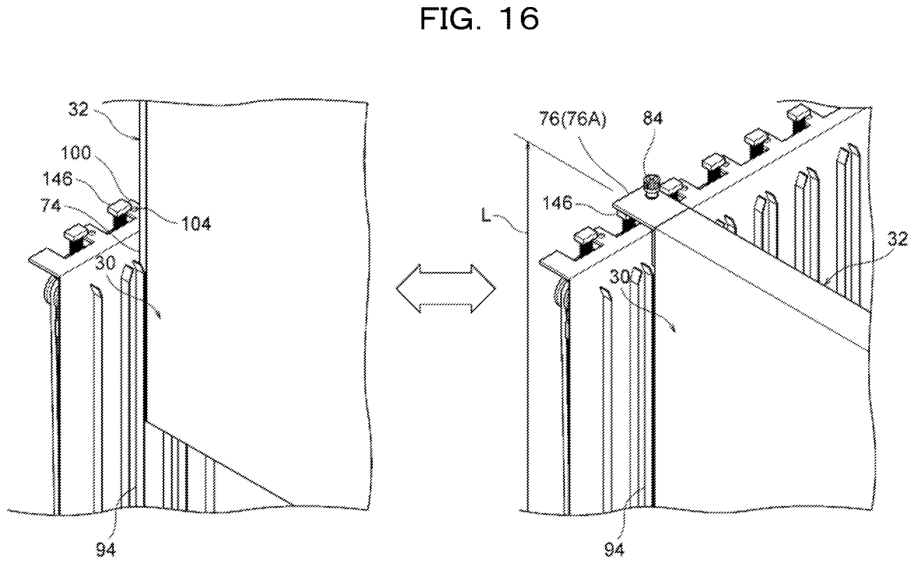

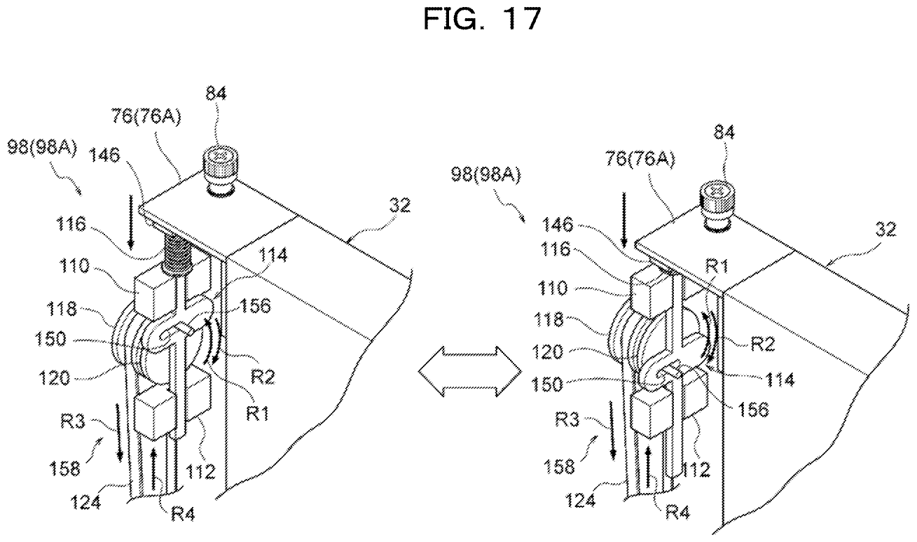

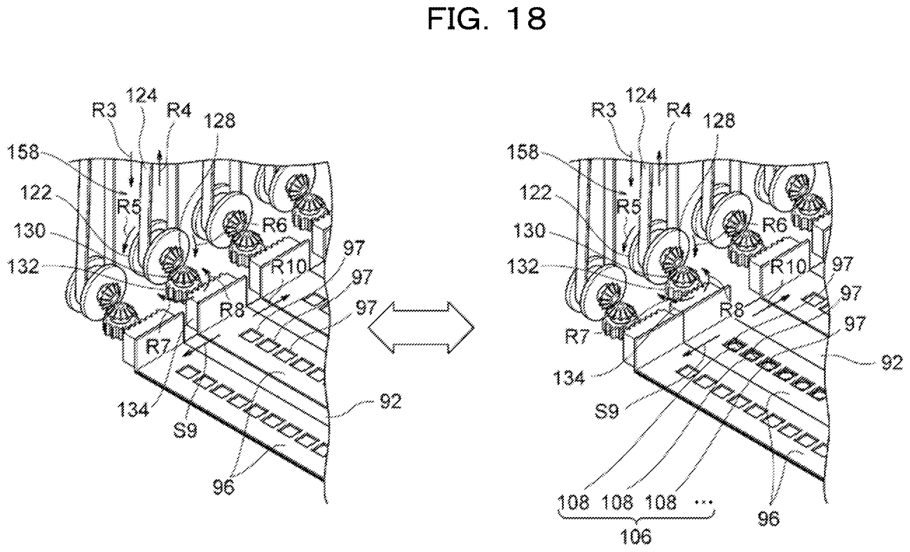

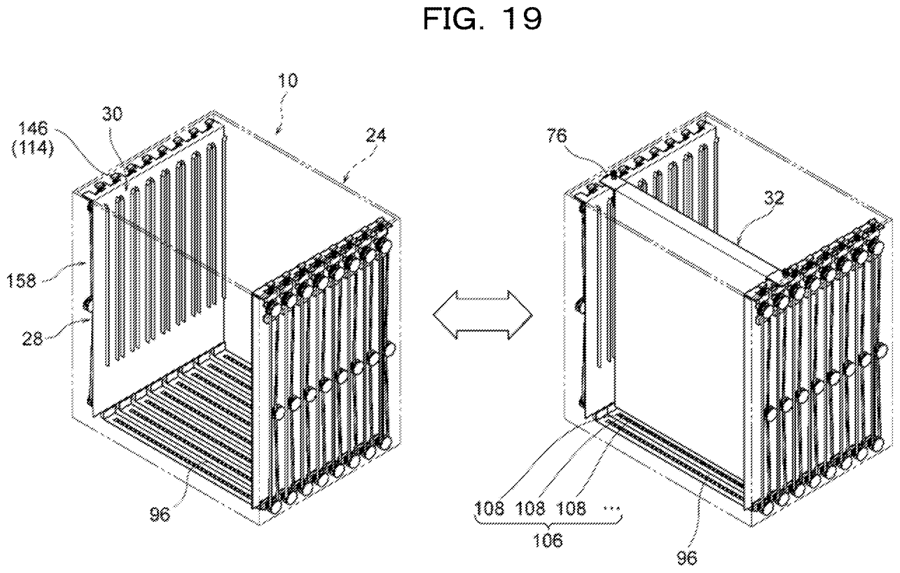

As an example, FIGS. 16 to 19 illustrate operations of the immersion tank 10 when the electronic device 32 is housed in or removed from the slot 30.

When the electronic device 32 is housed in the slot 30, the pushing target portion 146 is pushed downward by the flange 76. When the pushing target portion 146 is pushed downward, the moving member 114 moves downward. When the moving member 114 moves downward, the pin 156 moves in the slotted hole 150. This causes the first pulley 118 and the rotating member 120 to rotate in the first direction R1. When the first pulley 118 rotates in the first direction R1, the belt 124 rotates in the third direction R3.

When the belt 124 rotates in the third direction R3, the second pulley 122 and the first gear 128 rotate in the fifth direction R5. When the first gear 128 rotates in the fifth direction R5, the second gear 130 and the pinion 132 rotate in the seventh direction R7. When the pinion 132 rotates in the seventh direction R7, the rack 134 and the opening/closing member 96 slide in the ninth direction S9. When the opening/closing member 96 slides in the ninth direction 59, the opening/closing member 96 is displaced from the closed position to the open position.

When the opening/closing member 96 is displaced from the closed position to the open position, the plurality of supply holes 108 included in the supply hole row 106 corresponding to the slot 30 in which the electronic device 32 is housed are opened. When the plurality of supply holes 108 are opened, the coolant 26 (see FIG. 1) having flowed into the space between the bottom plate 44 and the bottom plate 92 through the coolant inlet 48 (see FIG. 1) is supplied to the inside of the housing unit 28 (for example, the slot 30 in which the electronic device 32 is housed) through the plurality of supply holes 108. The electronic device 32 is cooled by the coolant 26 supplied to the slot 30.

In contrast, when the electronic device 32 is removed from the slot 30, the pushing target portion 146 is pushed upward by the urging member 116. When the pushing target portion 146 is pushed upward, the moving member 114 moves upward. When the moving member 114 moves upward, the pin 156 moves in the slotted hole 150. This causes the first pulley 118 and the rotating member 120 to rotate in the second direction R2. When the first pulley 118 rotates in the second direction R2, the belt 124 rotates in the fourth direction R4.

When the belt 124 rotates in the fourth direction R4, the second pulley 122 and the first gear 128 rotate in the sixth direction R6. When the first gear 128 rotates in the sixth direction R6, the second gear 130 and the pinion 132 rotate in the eighth direction R8. When the pinion 132 rotates in the eighth direction R8, the rack 134 and the opening/closing member 96 slide in the tenth direction S10. When the opening/closing member 96 slides in the tenth direction 510, the opening/closing member 96 is displaced from the open position to the closed position.

When the opening/closing member 96 is displaced from the open position to the closed position, the plurality of supply holes 108 included in the supply hole row 106 corresponding to the slot 30 in which the electronic device 32 is housed are closed. When the plurality of supply holes 108 are closed, supply of the coolant 26 to the inside of the housing unit 28 (for example, the slot 30 from which the electronic device 32 has been removed) through the supply holes 108 is stopped.

The movement of the moving member 114 downward is an example of a “movement of the moving member to a first side” according to the technique of the present disclosure. The movement of the moving member 114 upward is an example of a “movement of the moving member to a second side opposite to the first side” according to the technique of the present disclosure.

Next, effects of the present embodiment will be described.

As described in detail above, the immersion tank 10 includes the moving member 114, the supply hole row 106, the opening/closing member 96, and the operatively associated mechanism 158. The moving member 114 is movably supported relative to the tank body 24. The supply hole row 106 is formed in the housing unit 28. The coolant 26 is supplied to the slot 30 inside the housing unit 28 through the supply hole row 106. The opening/closing member 96 is displaced from the closed position at which the opening/closing member 96 closes the supply hole row 106 to the open position at which the opening/closing member 96 opens the supply hole row 106. The operatively associated mechanism 158 displaces the opening/closing member 96 in accordance with the movement of the moving member 114. Accordingly, the opening/closing member 96 may be displaced from the closed position to the open position by moving the moving member 114 when the electronic device 32 is housed in the slot 30. Thus, in the case where the electronic device 32 is housed in the slot 30, the coolant 26 may be supplied to the slot 30 without using a pushing down member (for example, a member extending downward from the device body 72) for the electronic device 32.

The housing unit 28 has the plurality of slots 30 that houses the electronic devices 32, and the immersion tank 10 includes a plurality of the moving members 114, the plurality of supply hole rows 106, the plurality of opening/closing members 96, and a plurality of the operatively associated mechanisms 158. The plurality of moving members 114 respectively correspond to the plurality of slots 30. The plurality of supply hole rows 106 respectively corresponds to the plurality of slots 30. The plurality of opening/closing members 96 respectively correspond to the plurality of slots 30. The plurality of operatively associated mechanisms 158 respectively corresponds to the plurality of slots 30. Accordingly, the state where the supply hole row 106 is opened and the state where the supply hole row 106 is closed may be switched on a slot-30-by-slot-30 basis. Thus, supply of the coolant 26 to a slot 30 in which the electronic device 32 is not housed may be suppressed.

Since the supply of the coolant 26 to the slot 30 in which the electronic device 32 is not housed may be suppressed, the number of revolutions of the circulation pump 12 may be decreased compared to a case where the coolant 26 is supplied to the slot 30 in which the electronic device 32 is not housed. Accordingly, power to be used for driving the circulation pump 12 may be decreased compared to the case where the coolant 26 is supplied to the slot 30 in which the electronic device 32 is not housed.

The moving member 114 includes the pushing target portion 146. The pushing target portion 146 is provided at a position at which the pushing target portion 146 is pushed downward by the electronic device 32 when the electronic device 32 is housed in the slot 30. Accordingly, the moving member 114 may be moved when the electronic device 32 is housed in the slot 30. Accordingly, a special operation for displacing the opening/closing member 96 is not desired, thereby convenience of the immersion tank 10 may be improved.

In the case where the electronic device 32 is housed in the slot 30, the pushing target portion 146 is contained within the length range L of the electronic device 32 in the vertical direction. Accordingly, for example, an increase in the length of the electronic device 32 in the vertical direction may be suppressed compared to a case where a pushing portion provided in the electronic device 32 for pushing down the pushing target portion 146 projects from the length range L of the electronic device 32 in the vertical direction. Accordingly, the handleability of the electronic device 32 may be improved.

For example, even in a case where the electronic device 32 is a LAN switch having a device body 72 the length of which in the Z direction is smaller than that in the case where the electronic device 32 is an information processing device, an increase in the length of the electronic device 32 in the vertical direction may be suppressed, and accordingly, the handleability of the electronic device 32 may be improved.

The moving member 114 includes the projecting portion 148 that projects to the upper side compared to the fixing portion 100 formed at the upper end portion of the housing unit 28, and the pushing target portion 146 is provided at the projecting portion 148. Accordingly, in the case where the electronic device 32 is housed in the slot 30, the pushing target portion 146 may be pushed downward by the flange 76 until the flange 76 is superposed over the fixing portion 100. Thus, the moving member 114 may be moved downward when the electronic device 32 is housed in the slot 30.

The fixing portion 100 to which the flange 76 provided in the electronic device 32 is fixed is provided at the upper end portion of the housing unit 28, and the pushing target portion 146 is provided at a position where the pushing target portion 146 is pushed downward by the flange 76 when the electronic device 32 is housed in the slot 30. Accordingly, since the flange 76 to be fixed to the fixing portion 100 also serves as a pushing portion for pushing the pushing target portion 146 downward, the configuration of the electronic device 32 may be simplified compared to a case where a pushing portion other than the flange 76 is used.

The opening/closing mechanism 98 includes the urging member 116 that urges the moving member 114 upward. Accordingly, in the case where the electronic device 32 is removed from the slot 30, the moving member 114 may be moved upward by the urging force of the urging member 116. Thus, since a special operation for moving the moving member 114 upward in the case where the electronic device 32 is removed from the slot 30 is not desired, convenience of the immersion tank 10 may be improved.

The tank body 24 has the outer wall 46, and the housing unit 28 has the inner wall 90 facing the outer wall 46. The moving member 114 is disposed between the outer wall 46 and the inner wall 90. A space between the outer wall 46 and the inner wall 90 is a dead space. Accordingly, the dead space may be effectively used as an arrangement space for the moving member 114.

Out of the plurality of elements included in the operatively associated mechanism 158, the first pulley 118, the rotating member 120, the second pulley 122, the belt 124, the tension pulley 126, the first gear 128, the second gear 130, and the pinion 132 are disposed between the outer wall 46 and the inner wall 90. As described above, the space between the outer wall 46 and the inner wall 90 is a dead space. Accordingly, the dead space may be effectively used as an arrangement space for the first pulley 118, the rotating member 120, the second pulley 122, the belt 124, the tension pulley 126, the first gear 128, the second gear 130, and the pinion 132.

Next, modification examples of the present embodiment will be described.

According to the above-described embodiment, the operatively associated mechanism 158 includes the first pulley 118, the rotating member 120, the second pulley 122, the belt 124, the tension pulley 126, the first gear 128, the second gear 130, the pinion 132, and the rack 134. However, the operatively associated mechanism 158 may have a configuration other than the above description as long as the operatively associated mechanism 158 is a mechanism that displaces the opening/closing member 96 in accordance with the movement of the moving member 114.

Although the electronic device 32 has a size to be housed in one slot 30 according to the above-described embodiment, the electronic device 32 may have a size to be housed in a plurality of the slots 30.

In the above-described embodiment, the pushing target portion 146 may be provided at any position in the vertical direction as long as the pushing target portion 146 is contained within the length range L of the electronic device 32 in the vertical direction in the case where the electronic device 32 is housed in the slot 30.

Although the moving member 114 including the pushing target portion 146 is supported so as to be movable in the vertical direction relative to the tank body 24 according to the above-described embodiment, the moving direction of the moving member 114 including the pushing target portion 146 may be a direction parallel to the vertical direction or a direction inclined relative to the vertical direction.

The embodiment of the technique disclosed in the present application has been described above. However, of course, the technique disclosed in the present application is not limited to the above description, and various modifications other than the above description may be made without departing from the gist thereof.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An immersion tank comprising:
a tank body that stores coolant;
a housing that is provided inside the tank body and that houses an electronic circuit;
a moving member movably supported relative to the tank body;
a supply hole which is formed in the housing and through which the coolant is supplied to an inside of the housing;
an opening/closing member that is displaced from a closed position at which the opening/closing member closes the supply hole to an open position at which the opening/closing member opens the supply hole; and
an operatively associated mechanism that displaces the opening/closing member in accordance with movement of the moving member.

2. The immersion tank according to claim 1, wherein
the housing has a plurality of slots that house a plurality of the electronic circuits, and wherein
the immersion tank includes
a plurality of the moving members that respectively correspond to the plurality of slots,
a plurality of the supply holes that respectively correspond to the plurality of slots,
a plurality of the opening/closing members that respectively correspond to the plurality of slots, and
a plurality of the operatively associated mechanisms that respectively correspond to the plurality of slots.

3. The immersion tank according to claim 1, wherein
the moving member is supported so as to be movable in the vertical direction relative to the tank body.

4. The immersion tank according to claim 3, wherein
the opening/closing member is supported so as to be displaceable in the horizontal direction with respect to the tank body.

5. The immersion tank according to claim 3, wherein
the moving member includes a pushing target portion provided at a position at which the pushing target portion is pushed downward by the electronic circuit when the electronic circuit is housed in the housing, and wherein,
in a case where the electronic circuit is housed in the housing unit, the pushing target portion is contained within a length range of the electronic circuit in a vertical direction.

6. The immersion tank according to claim 5, wherein
the moving member includes a projecting portion that projects to an upper side compared to an upper end portion of the housing, and wherein
the pushing target portion is provided at the projecting portion.

7. The immersion tank according to claim 5, wherein
a fixing portion to which a flange provided in the electronic circuit is fixed is provided at the upper end portion of the housing, and wherein
the pushing target portion is provided at a position at which the pushing target portion is pushed downward by the flange when the electronic circuit is housed in the housing.

8. The immersion tank according to claim 3, further comprising:
an urging member that urges the moving member upward.

9. The immersion tank according to claim 1, wherein
the tank body includes an outer wall,
the housing includes an inner wall facing the outer wall, and
the moving member is disposed between the outer wall and the inner wall.

10. The immersion tank according to claim 9, wherein
at least some of elements included in the operatively associated mechanism are disposed between the outer wall and the inner wall.

11. The immersion tank according to claim 1, wherein
the housing includes a bottom plate,
the supply hole is formed in the bottom plate, and
the opening/closing member is disposed above the bottom plate.

12. The immersion tank according to claim 1, wherein
at one side of the housing, a first moving member and a first operatively associated mechanism are provided, and
at another side of the housing opposite to the one side, a second moving member and a second operatively associated mechanism are provided.

13. The immersion tank according to claim 1, wherein
the operatively associated mechanism includes:
a first pulley,
a pin disposed on the first pulley,
a slotted hole formed on the moving member and inserted with the pin,
a second pulley disposed below the first pulley,
a belt looped over the first pulley and the second pulley,
a first gear provided so as to be integral with the second pulley,
a second gear engaged with the first gear,
a pinion provided so as to be integral with the second gear, and
a rack disposed on the opening/closing member and engaged with the pinion.

14. An information processing apparatus comprising:
an immersion tank, and
an electronic circuit,
wherein the immersion tank comprising:
a tank body that stores coolant;
a housing that is provided inside the tank body and that houses the electronic circuit;
a moving member movably supported relative to the tank body;
a supply hole which is formed in the housing and through which the coolant is supplied to an inside of the housing;
an opening/closing member that is displaced from a closed position at which the opening/closing member closes the supply hole to an open position at which the opening/closing member opens the supply hole; and
an operatively associated mechanism that displaces the opening/closing member in accordance with movement of the moving member.

15. A method of cooling an electronic circuit by using an immersion tank that includes
a tank body that stores coolant;
a housing that is provided inside the tank body and that houses the electronic circuit;
a moving member movably supported relative to the tank body;
a supply hole which is formed in the housing and through which the coolant is supplied to an inside of the housing;
an opening/closing member that is displaced from a closed position at which the opening/closing member closes the supply hole to an open position at which the opening/closing member opens the supply hole; and
an operatively associated mechanism that displaces the opening/closing member in accordance with movement of the moving member,
wherein the method comprising:
moving the moving member, according to housing the electronic circuit in the housing, by the electronic circuit to a first side;
displacing the opening/closing member from the closed position to the open position, according to the movement of the moving member to the first side, and open the supply hole;
supplying the coolant to inside the housing through the supply hole; and
whereby cooling the electronic circuit by the coolant.

16. The method of cooling the electronic circuit according to claim 15, wherein the method further comprising:
moving the moving member, according to removing the electronic circuit from the housing, to a second side opposite to the first side;
displacing the opening/closing member from the open position to the closed position, according to the movement of the moving member to the second side, and close the supply hole; and
stopping supplying the coolant inside the housing through the supply hole.
